(19) United States
(12) Patent Application Publication
(10) Pub. No.: US 2008/0079128 A1
(43) Pub. Date: Apr. 3, 2008

(54) LEAD FRAME TYPE STACK PACKAGE AND METHOD O FABRICATING THE SAME

(75) Inventors: Hyo-Jae BANG, Chungcheongnam-do (KR); Seong-Chan HAN, Chungcheongnam-do (KR); Hun HAN, Chungcheongnam-do (KR); Dong-Chun LEE, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/855,951

(22) Filed: Sep. 14, 2007

(30) Foreign Application Priority Data
Sep. 29, 2006 (KR) 2006-0096401

(51) Int. Cl. H01L 23/495; H01L 21/60

(52) U.S. Cl. 257/677; 438/109; 257/E21.506; 257/E23.031

(57) ABSTRACT

A lead frame type stack package in which a lead of the package is well connected to a semiconductor module, and a method of fabricating the same are provided. A lead of an upper package and a lead of a lower package are connected using laser soldering. Since leads of the upper and lower packages are connected by solder balls without the use of a soldering pot, loss of a plating layer of the lead due to solder dipping is prevented and the leads are well connected without soldering defects when connecting the lead of the lower package to a connection pad of a semiconductor module substrate.

### CROSS-REFERENCE TO RELATED PATENT APPLICATION

This application claims the benefit of Korean Patent Application No. 10-2006-0096401, filed on Sep. 29, 2006, in the Korean Intellectual Property Office, the disclosure of which is incorporated herein by reference.

### BACKGROUND

1. Field of the Invention

The present invention relates to a semiconductor package and a method of fabricating the same, and more particularly, to a lead frame type stack package and a method of fabricating the same.

2. Description of the Related Art

With the miniaturization and the increased capacity of electrical goods and electronics, high capacity semiconductor modules are required. High capacity semiconductor modules can be provided using a densely-integrated semiconductor chip, or they can be provided by mounting a plurality of semiconductor chips in a semiconductor package or integrating a plurality of semiconductor packages. High integration of semiconductor chips requires complex technological advances, such as reducing fine line width, which in turn require substantial development time. Meanwhile, since the capacity increase of semiconductor packages in the levels of a package or semiconductor module can be relatively easily embodied using stack technology, research and development of the stack package technology has been actively pursued. The stack package is advantageous as it increases the efficiency of mounting density and mounting area as well as increasing memory capacity.

FIG. 1 is a schematic sectional view of a thin small outline package (TSOP) type two-layered stack package using lead frames. The TSOP package comprises an upper and lower package 10 and 20, which respectively include bodies 11 and 21 and leads 13 and 23 extending from the bodies 11 and 21. In the TSOP stack package shown in FIG. 1, the leads 13 of the upper package 10 is connected to the leads 23 of the lower package 20. The connection of the leads 13 and 23 is made using solder dipping, which is performed in such a manner that the bodies 11 and 21 of the stack packages 10 and 20 contact each other, the leads 13 and 23 of the upper and lower packages 10 and 20 meet together, and the resulting structure is immersed into a soldering pod.

Since the leads function to electrically connect the semiconductor chip and external circuits, the leads must have good electric conductivity and good solder characteristics. To this end, the leads are generally composed of metal alloy having good electric conductivity and a plating layer having good solder characteristics surrounding the metal alloy. The metal alloy generally comprises copper (Cu) or gold (Au), and the plating layer comprises tin (Sn) as a main element.

However, the plating layer of the leads may be damaged during the process of connecting the leads 13 and 23 in the solder dipping. FIG. 2 is a photograph illustrating a section of one lead where the plating layer is damaged after connecting the upper and lower leads by the solder dipping. In the lead shown in FIG. 2, a plating layer 23b exists only on the upper surface of a metal alloy portion 23a, however, the plating usually surrounds the metal alloy portion. If the plating layer does not surround the metal alloy portion, the lead cannot be well connected to the semiconductor module.

FIGS. 3A and 3B illustrate a situation where a lead with the plating layer lost and damaged is poorly connected to a connection pad of the semiconductor module by soldering. FIG. 3C is a photograph of a sectional view illustrating that the lead having a damaged plating layer is poorly connected to the connection pad of the semiconductor module. Referring to FIGS. 3A through 3C, after a connection pad 63 of the semiconductor module is coated with a solder powder 65, and a package lead (lower lead of the stack package) 23 is placed, heat is applied. At this time, the solder 65, which is melted by the heat, is spread along the plating layer 23b of the lead 23 to cover the lead 23, thereby forming a fillet with the solder. However, if the plating layer 23b of the lead 23 is damages or is poorly formed, the solder 65 cannot surround the lead 23 as shown in FIG. 3B, and thus is only formed under the lead 23. After soldering, since the solder 65′ is formed only under the lead 23 as shown in FIG. 3C, and a fillet is not formed on sides of the lead 23, the soldering is not completely and successfully made. A reference numeral 23a represents a metal alloy portion.

It is understood that the loss of the plating layer of the lead by the solder dipping is because the plating layer component of the lead immersed in a solder dipping solution is diffused out into the solder dipping solution.

### SUMMARY

Embodiments of the present invention provide a lead frame type stack package in which the plating layer of a lead is not damaged and the lead is well connected to a semiconductor module by soldering when a lead of an upper package is connected to a lead of a lower package.

The present invention also provides a method of fabricating a lead frame type stack package, in which the plating layer of a lead is not damaged and the lead is well connected to a semiconductor module by soldering when a lead of an upper package is connected to a lead of a lower package.

According to an embodiment of the present invention, a lead frame type stack package includes a first lead frame type package comprising a body including a semiconductor chip and a plurality of leads extending from the body, and a second lead frame type package stacked on the first package and comprising a body including a semiconductor chip and a plurality of leads extending from the body. The leads of the second package are connected to the leads of the first package using a solder ball, where each of the leads of the first and second packages include a metal alloy portion and a plating layer completely surrounding the metal alloy portion.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic sectional view illustrating a TSOP (thin small outline package) type two-layered stack package using a conventional lead frame;

FIG. 2 is a photograph of a sectional view of a lead showing an example of the damage a plating layer can sustain after upper and lower leads are connected by solder dipping in the conventional stack package illustrated in FIG. 1;

FIGS. 3A and 3B are views illustrating a lead with the plating layer lost and damaged that is poorly connected to a connection pad of the semiconductor module by soldering according to the conventional art;

FIG. 3C is a photograph of a sectional view showing an example of the damage in the leads illustrated in FIGS. 3A and 3B;

FIG. 4 is a photograph of a sectional view showing a lead frame type stack package according to an embodiment of the present invention;

FIG. 5 is a photograph of a sectional view showing the lead after upper and lower leads are connected by solder balls in the stack package shown in FIG. 4;

FIG. 6 illustrates a soldering process using laser according to an embodiment of the present invention;

FIGS. 7A and 7B illustrate a lead having a plating layer formed thereon and connected to a connection pad of a semiconductor module by soldering according to an embodiment of the present invention; and

FIG. 7C is a photograph showing the lead illustrated in FIGS. 7A and 7B.

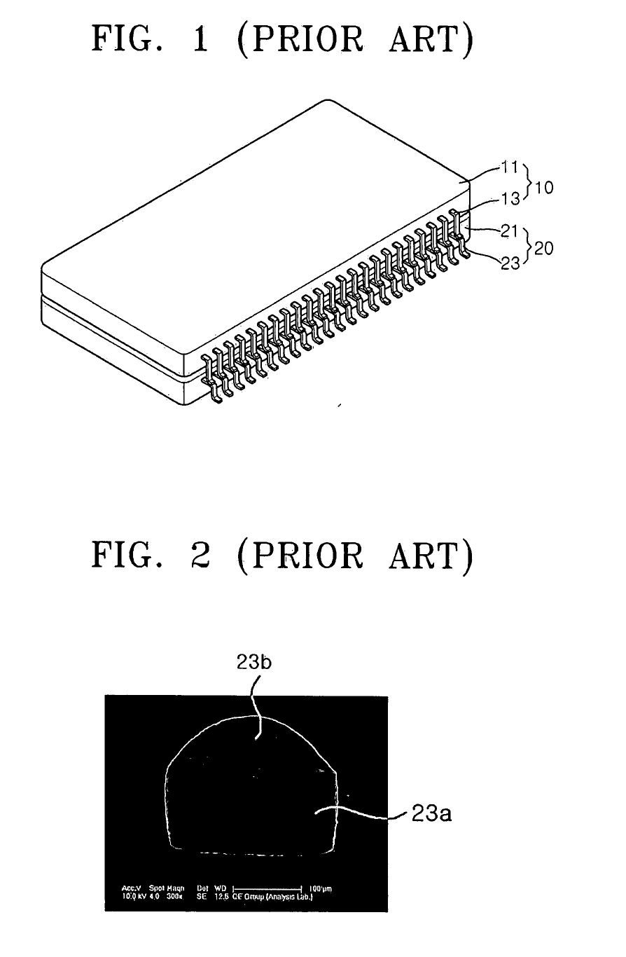

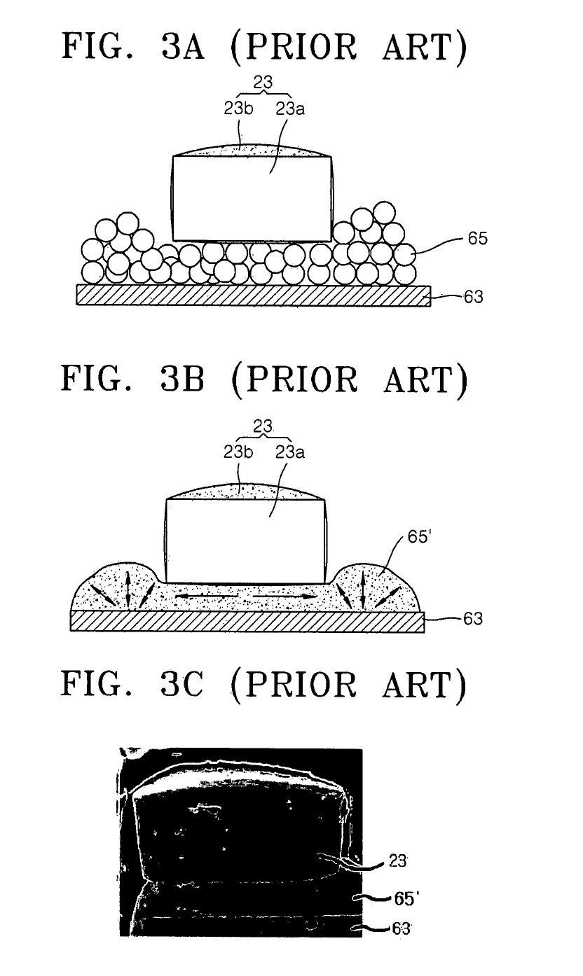

### DETAILED DESCRIPTION

The present invention will now be described more fully hereinafter with reference to the accompanying drawings, in which exemplary embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

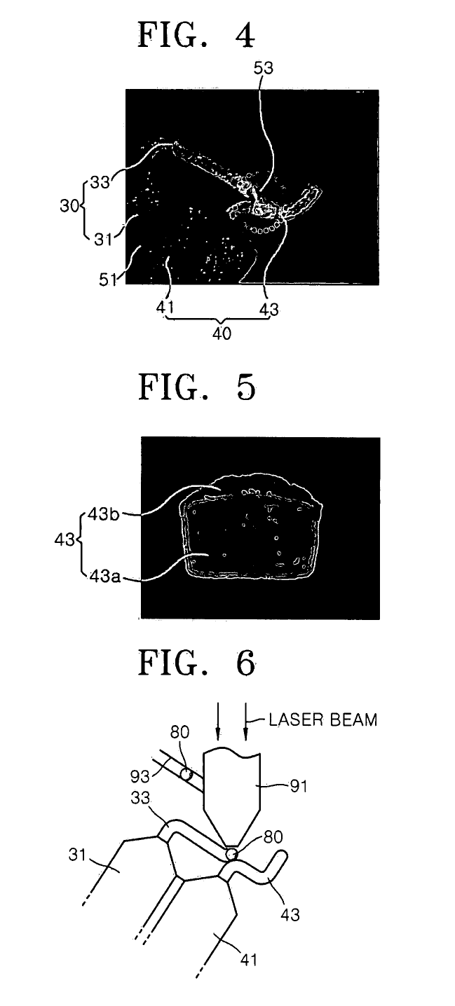

FIG. 4 is a photograph of a sectional view showing a lead frame type stack package according to an embodiment of the present invention. The stack package of FIG. 4 is a two-layered package composed of a lower package and an upper package. Each package is a thin small outline package (TSOP) type package. Leads 33 and 43 are extended from bodies 31 and 41. The lead 33 of the upper package 30 is connected to the lead 43 of the lower package 40 by a solder ball 53. The solder ball 53 may be formed using laser soldering, and has a diameter similar to that of each of the leads 33 and 43. The bodies of the upper package 30 and the lower package 40 may be bonded by an adhesives 51 disposed therebetween. Since the lead 33 of the upper package 30 and the lead 43 of the lower package 40 are connected by a solder ball 53, the loss of a lead plating layer, which may be generated by the connection using solder dipping, does not occur.

FIG. 5 is a photograph of a sectional view showing a lead 43 of a lower package 40 after the lead is connected by a solder ball in the stack package shown in FIG. 4. As shown in FIG. 5, a plating layer 43b completely covers a metal alloy portion 43a. The metal alloy portion 43a may be composed of alloy having a good electric conductivity and comprising copper (Cu) or gold (Au) as main elements. The plating layer 43b may be composed of metal such as SnAgCu, in which tin (Sn) is a main element.

A stack package is mounted on the semiconductor module by the lead 43 of the lower package being connected to a connection pad of a semiconductor module with solder. In the current embodiment, since the plating layer 43b, which functions to help the wetting of the solder, is not lost, the solder is well wetted to the lead 43 of the lower package 40 so that the solder connection is successfully made.

In the current embodiment, the TSOP type stack package has been explained, but the present invention can be also employed to other types of packages using a lead frame, for example, a quad flat package (QFP). Further, the current embodiment has explained a two-layered stack package, but the present invention can be also employed to a three-layered or more stack package. In addition, a unit package of the stack package may comprise a single semiconductor chip, or may comprise a plurality of semiconductor chips.

A method of fabricating the lead frame type stack package as shown in FIG. 5 will be explained as follows. Lead frame type packages such as TSOP are stacked up and down. At this time, the leads of the upper package and the leads of the lower package are arranged to respectively contact each other. The bodies of the upper package and the lower package may further be bonded by adhesives. Then, the leads of the upper package and the leads of the lower package are connected using laser soldering. Three or more lead frame type packages may be stacked using the laser soldering. That is, another package may be stacked on the upper package of the stack package with the leads of the upper package being connected to the leads of the other package by laser soldering. Additional packages may be further stacked on the other package in a similar manner.

FIG. 6 illustrates a laser soldering process according to an embodiment of the present invention. Referring to FIG. 6, a solder ball 80 comes out from a nozzle of a laser soldering head 91 and is disposed at a connection point between the upper and lower leads 33 and 43. A laser beam is irradiated to the solder ball 80 supplied from the side 93 of the laser soldering head 91 to the nozzle of the laser soldering head 91 to melt the solder ball 80. The melted solder ball 80 is pulled out of the nozzle by exhaust gas such as an inert gas. The laser beam may use a Nd:YAG laser, for example. While the solder ball 80, which comes out to the connection of the leads and is melted, is cured, the leads 33 and 43 of the upper and lower packages 31 and 41 can be connected.

At this time, the laser soldering head 91 may be placed at any direction, for example, vertically or tiltedly. And also, the stack package may be placed at any direction.

According to the present invention, when the lead bonding method using the solder ball 80 is used, the problem of losing the plating layer is solved since the plating layer of the lead does not diffuse into a soldering pot.

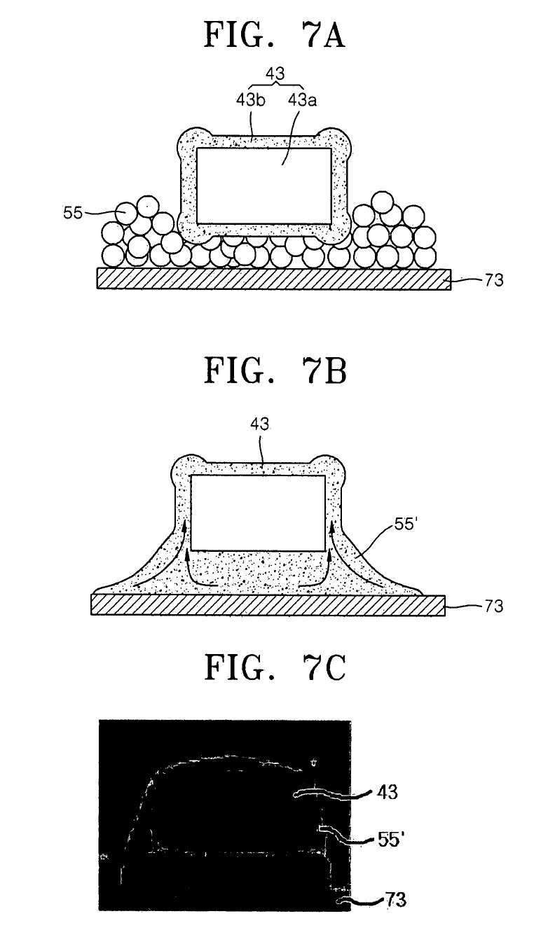

FIGS. 7A and 7B illustrate a lead having a plating layer formed thereon and connected to a connection pad of a semiconductor module by soldering according to an embodiment of the present invention. FIG. 7C is a photograph showing the lead illustrated in FIGS. 7A and 7B. Referring to FIGS. 7A and 7B, a lead 43 of a stack package is placed on a connection pad 73 of a semiconductor module, which is coated with a soldering powder 55 including a metal powder, such as SnAgCu. When heat is applied to reflow the soldering powder 55, the soldering powder 55 is spread along the surface of a plating layer 43b of the lead 43 so as to form a fillet 55′. When the plating layer 43b is well formed on the surface of the lead 43, the fillet 55′ connecting the lead 43 to the connection pad 73 is uniformly formed along the plating layer so that a stack package is firmly connected to the connection pad of the semiconductor module. Hence, the stack packages are firmly connected in the module, thereby increasing the reliability of the products that contain these stacked packages.

The lead frame type stack package according to embodiments of the present invention is formed by connecting the leads of the upper package and the leads of the lower package using laser soldering. Since the leads of the upper and lower packages are connected using solder balls rather than being immersed into a soldering pot, loss of the plating layer of the lead caused due to solder dipping can be prevented. Thus, the leads of the lower package can be well connected to the connection pad of the semiconductor module without soldering defects.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A lead frame type stack package comprising:
a first lead frame type package comprising a body including a semiconductor chip and at least one lead extending from the body;
a second lead frame type package comprising a body including a semiconductor chip and at least one lead extending from the body, the second lead frame type package stacked on the first lead frame type package; and
a solder ball connecting the lead of the second lead frame type package to the lead of the first lead frame type package,
wherein each of the leads of the first and second lead frame type packages comprises a metal alloy portion and a plating layer substantially surrounding the metal alloy portion.

2. The lead frame type stack package of claim 1, wherein at least one additional lead frame type package is further stacked on the second lead frame type package by connecting at least one lead of the additional lead frame style package to at least one lead of the second lead frame type package using a solder ball.

3. The lead frame type stack package of claim 1, wherein the solder ball is formed by a laser soldering method.

4. The lead frame type stack package of claim 1, wherein the metal alloy portion comprises copper (Cu) or gold (Au).

5. The lead frame type stack package of claim 1, wherein the plating layer comprises tin (Sn).

6. The lead frame type stack package of claim 1, wherein the first and second lead frame type packages are thin small outline package (TSOP) lead frame type stack packages.

7. The lead frame type stack package of claim 1, wherein the first and second lead frame type packages are quad flat package (QFP) lead frame type stack packages.

8. A method of fabricating a lead frame type stack package comprising a plurality of lead frame type stack packages, each package including a body and at least one lead extending from the body, the method comprising:
stacking a second lead frame type package on a first lead frame type package to bring the lead of the second lead frame type package in contact with the lead of the first lead frame type package; and
connecting the lead of the first lead frame type package to the lead of the second lead frame type package using laser soldering.

9. The method of claim 8, further comprising:
stacking a third lead frame type package on the second lead frame type package by partially contacting a lead of the third lead frame type package on a lead of the second lead frame type package; and
connecting the lead of the second lead frame type package with the lead of the third lead frame type package using laser soldering.

10. The method of claim 8, wherein the laser soldering is perform fled by placing a solder ball on a connection portion of the leads, melting the solder ball by a laser beam, and curing the solder ball to bond the leads to each other.

11. The method of claim 10, wherein the laser beam is generated from a Nd:YAG laser.

12. The method of claim 8, wherein the first and second lead frame type packages are TSOP lead frame type stack packages.

13. The method of claim 8, wherein the first and second lead frame type packages are QFP lead frame type stack packages.

14. The method of claim 8, wherein the lead comprises a metal alloy portion and a plating layer completely surrounding the metal alloy portion.

15. A semiconductor module comprising:
a first lead frame type package comprising a body including a semiconductor chip and a plurality of leads extending from the body;
a second lead frame type package comprising a body including a semiconductor chip and a plurality of leads extending from the body, and the second lead frame type package stacked on the first lead frame type package;
a solder ball connecting the leads of the second lead frame type package to the leads of the first lead frame type package; and
a module substrate comprising a plurality of connection pads, in which the leads of the first lead frame type package are respectively connected to the connection pads.

16. The module of claim 15, wherein each of the leads of the first and second lead frame type packages comprises a metal alloy portion and a plating layer substantially surrounding the metal alloy portion.

17. The module of claim 16, wherein the metal alloy portion comprises copper (Cu) or gold (Au).

18. The module of claim 16, wherein the plating layer comprises tin (Sn).

19. The module of claim 16, wherein the first and second lead frame type packages are thin small outline package (TSOP) lead frame type stack packages.

20. The module of claim 16, wherein the first and second lead frame type packages are quad flat package (QFP) lead frame type stack packages.
